(19) United States
(12) Patent Application Publication
(10) Pub. No.: US 2009/0261850 A1
(43) Pub. Date: Oct. 22, 2009

(54) Probe card

(75) Inventor: Hongchan Kim, Gyeonggi-do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Willtechnology Co., Ltd., Gyeonggi-do (KR)

(21) Appl. No.: 12/157,514

(22) Filed: Jun. 11, 2008

(30) Foreign Application Priority Data
Apr. 21, 2008 (KR) 10-2008-0036516

(51) Int. Cl. G01R 1/073

(52) U.S. Cl. 324/754

(57) ABSTRACT

Disclosed is a probe card capable of simplifying the manufacturing process and the repair work. The probe card includes a printed circuit board including a substrate through hole; at least one probe substrate disposed on the printed circuit board; at least one probe including a probe body supported by the probe substrate and a probe lead part extending from the probe body to an inside of the substrate through hole in the printed circuit board; and a guide block disposed between the printed circuit board and the probe substrate, and including a block through hole through which the probe lead part passes, wherein the probe is fixed to the probe substrate by moving the guide block in a Y axis direction so that the probe lead part is bent in the Y axis direction.

### FIELD OF THE INVENTION

The present disclosure relates to a probe card including a printed circuit board; and, more particularly, to a probe card having a bendable probe.

### BACKGROUND OF THE INVENTION

Generally, a semiconductor device is manufactured through a fabrication process, which forms a circuit pattern and a contact pad for testing on a wafer, and an assembly process, which assembles the wafer formed with the circuit pattern and the contact pad into individual semiconductor chips.

Between the fabrication process and the assembly process, a test process, which tests an electrical characteristic of the wafer by applying an electrical signal to the contact pad formed on the wafer, is performed. The test process is performed to remove a defected portion of the wafer by detecting defects of the wafer during the assembly process.

For the test process, a testing device called a tester which applies an electrical signal to the wafer and another device called a probe card which serves as an interface between the wafer and the tester are usually used. Among them, the probe card includes a printed circuit board which receives the electrical signal applied from the tester, and a plurality of probes which make contact with the contact pads formed on the wafer.

In a conventional probe card, a connection between the printed circuit board and the probe is achieved by bonding the probe with a conductive pattern formed on a space transformer which is composed of the printed circuit board or a multi layer ceramic (MLC) substrate by using an adhesive member or mechanical tools such as a laser. Also the connection is achieved by inserting the probe into the printed circuit board or by allowing the probe to elastically respond to the printed circuit board so that the probe is brought into contact with the conductive pattern formed on the printed circuit board.

When directly connecting the printed circuit board with the probe, there is a problem of using the expensive space transformer made of the multi layer ceramic substrate for performing a space transformation between the printed circuit board and the probe because it is difficult for the probe to correspond to a microscopic pitch between the contact pads formed on the wafer.

Also, in case of boding the probe with the conductive pattern formed on the printed circuit board, since an additional boding process is carried out, there is a problem of increasing manufacturing time and manufacturing costs of the probe card.

Further, in case of bonding the probe with the conductive pattern formed on the space transformer, if a defect occurs during the boding process, there is a problem of being unable to reuse the space transformer relative to the bonding process.

Furthermore, when the probe makes contact with the conductive pattern formed on the printed circuit board, since a structural shape of the probe and the printed circuit board related to the contact has to be adjusted or an additional member related to the contact has to be included, there is the problem of increasing manufacturing time and manufacturing costs of the probe card.

Additionally, if the defect occurs on the probe by several rounds of the test process, it is troublesome to remove the bonding part between the probe card and the printed circuit board or the space transformer, and replace the defected probe with a new probe, and then again bond the probe with the printed circuit board or the space transformer in order to replace the defected probe with the new probe. Also it is difficult to adjust the planarization between the replaced probe and the rest of probes. Thus, there is a problem of increasing maintenance costs of the probe card.

### BRIEF SUMMARY OF THE INVENTION

In view of the foregoing, the present disclosure provides a probe card capable of reducing the manufacturing time, the manufacturing costs and the maintenance costs thereof by simplifying the manufacturing process and the repair work thereof.

Further, the present disclosure provides a probe card capable of easily adjusting the planarization thereof, and not requiring a space transformer.

In accordance with an embodiment of the present invention, there is provided a probe card including: a printed circuit board including a substrate through hole; at least one probe substrate disposed on the printed circuit board; at least one probe including a probe body supported by the probe substrate and a probe lead part extending from the probe body to an inside of the substrate through hole in the printed circuit board; and a guide block disposed between the printed circuit board and the probe substrate, and including a block through hole through which the probe lead part passes, wherein the probe is fixed to the probe substrate by moving the guide block in a Y axis direction so that the probe lead part is bent in the Y axis direction.

The substrate through hole of the printed circuit board and the block through hole of the guide block are formed so that the probe lead part is freely extended.

A conductive material is formed on an inner surface of the substrate through hole, and an end portion of the probe lead part is supported by the conductive material while making contact with the conductive material when the probe lead part is bent in the Y axis direction.

A conductive material is formed on an inner surface of the block through hole, and a center portion of the probe lead part is supported by the conductive material while making contact with the conductive material when the probe lead part is bent in the Y axis direction.

A first space is formed between the probe substrate and the guide block and a second space formed between the guide block and the printed circuit board so that the probe lead part is bent.

A lower stiffener is disposed between the guide block and the printed circuit board.

The lower stiffener includes at least one receiving groove extending in the Y axis direction, and the guide block is received in the receiving groove.

A protruded rail extending in the Y axis direction is formed on one side surface of the lower stiffener and the probe substrate which are facing each other, and a grooved rail structurally coupled to the protruded rail is formed on the other side surface of the lower stiffener and the probe substrate.

A cover surrounds a contour of the probe substrate and a contour of the guide block.

The cover includes a hollow part formed to expose the probe body and a protruded wall formed along a peripheral portion of the hollow part.

An adjusting screw passes through the protruded wall to be coupled to a side surface of the guide block, wherein the guide block is pushed or pulled in the Y axis direction by turning the adjusting screw.

The probe substrate includes a probe substrate body and at least one probe through hole which is formed by passing through the probe substrate body.

The probe substrate body includes a ceramic substrate.

The probe through hole is formed by a photolithography process.

The probe substrate body includes at least one fixing slit which extends in an X axis direction at one side surface of the probe substrate body where the probe body is exposed, and has a width substantially equal to a thickness of the probe; and at least some of the probe body is received in the fixing slit so that the probe is arranged in the Y axis direction.

The probe substrate body further includes at least one first groove which extends in the Y axis direction at the other side surface facing the one side surface; and the probe through hole is formed in an intersecting portion of the fixing slit and the first groove.

The fixing slit and the first groove are formed by a dicing process.

The probe substrate body further includes at least one guide hole which extends from the other side surface facing the one side surface to the fixing slit; and the probe through hole is formed by communicating the fixing slit with the guide hole.

The fixing slit is formed by a dicing process and the guide hole is formed by a drilling process.

The probe substrate body further includes at least one second groove which extends in the Y axis direction at the one side surface of the probe substrate body where the probe body is exposed, and the probe body has a width substantially equal to a width of the second groove; and a protruded part is received in the second groove so that the probe is arranged in the X axis direction.

Each probe lead part of the adjacent probes is connected with each probe body at different positions.

An upper stiffener is disposed on an upper part of the printed circuit board.

A probe substrate fixing screw is inserted into the probe substrate to be coupled with the upper stiffener.

In accordance with an embodiment of the present invention, the manufacturing process and the repair work for the probe card is simplified by using a bendable probe, thereby reducing the manufacturing time, the manufacturing costs and the maintenance costs thereof.

Further, the planarization adjustment is facilitated by using the probe substrate and the space transformer is not required.

### BRIEF DESCRIPTION OF THE DRAWINGS

The disclosure may best be understood by reference to the following description taken in conjunction with the following figures:

FIG. 1 is an exploded perspective view of a probe card in accordance with a first embodiment of the present invention;

FIG. 2 depicts an enlarged view illustrating A portion of FIG. 1;

FIG. 3 shows an enlarged view illustrating B portion of FIG. 1;

FIG. 4 illustrates an enlarged view illustrating C portion of FIG. 1;

FIG. 5 is an enlarged view illustrating D portion of FIG. 1;

FIG. 6 depicts a rear view of FIG. 5;

FIG. 7 shows a cross sectional view taken along line VII-VII in FIG. 6;

FIG. 8 illustrates an enlarged perspective view illustrating a portion of a plurality of probes illustrated in FIG. 1;

FIG. 9 is an enlarged rear view of E portion of FIG. 1;

FIG. 10 depicts a plan view of a probe card in accordance with a first embodiment of the present invention;

FIG. 11 shows a cross sectional view taken along line XI-XI of FIG. 10;

FIG. 12 illustrates a cross sectional view taken along line XII-XII of FIG. 10;

FIG. 13 is a cross sectional view when a guide block is moved in FIG. 12;

FIG. 14 depicts a partially enlarged perspective view of a probe substrate included in a probe card in accordance with a second embodiment of the present invention;

FIG. 15 shows a rear view of FIG. 14; and

FIG. 16 illustrates a cross sectional view taken along line XVI-XVI of FIG. 15.

### DETAILED DESCRIPTION OF THE INVENTION

Hereinafter, embodiments of the present invention will be described in detail with reference to the accompanying drawings so that the present invention may be readily implemented by those skilled in the art. However, it is to be noted that the present invention is not limited to the embodiments but can be realized in various other ways. In the drawings, parts irrelevant to the description are omitted for the simplicity of explanation, and like reference numerals denote like parts through the whole document.

Through the whole document, the term “on” that is used to designate one element being on another element includes both a case that an element is “directly on” another element and a case that an element is “on” another element via still another element. Further, the term “comprises or includes” and/or “comprising or including” used in the document means that one or more other components, steps, operation and/or existence or addition of elements are not excluded in addition to the described components, steps, operation and/or elements.

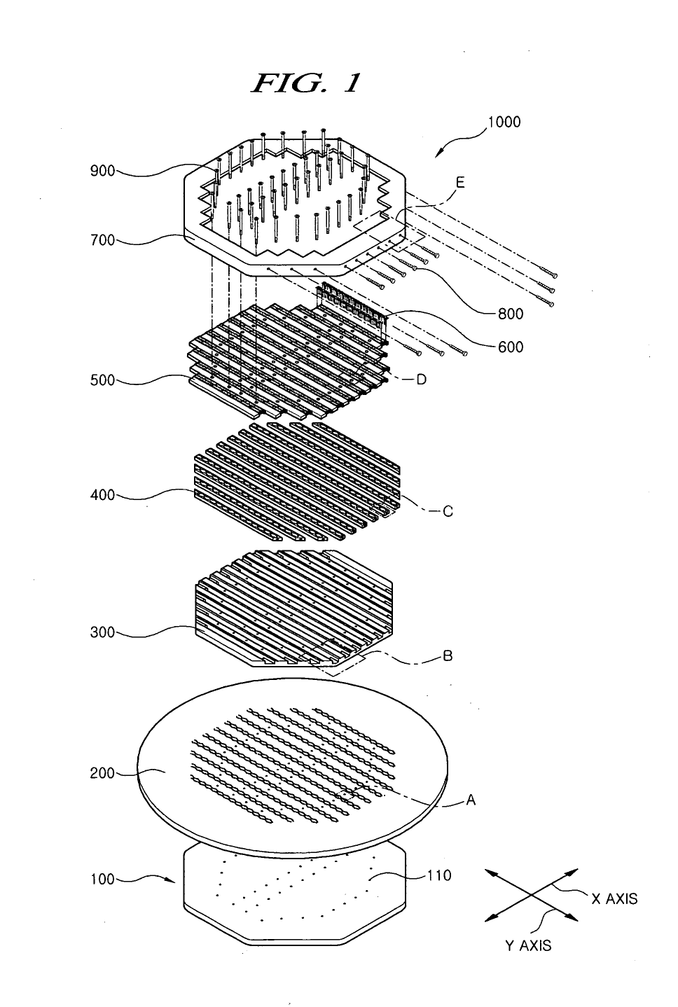

Hereinafter, in reference to FIGS. 1 thru 13, a probe card 1000 in accordance with a first embodiment of the present invention will be described.

FIG. 1 is an exploded perspective view illustrating the probe card in accordance with the first embodiment of the present invention. In FIG. 1, only a portion of the probe is illustrated for convenience sake.

As illustrated in FIG. 1, the probe card 1000 in accordance with the first embodiment of the present invention includes an upper stiffener 100, a printed circuit board 200, a lower stiffener 300, a guide block 400, a probe substrate 500, a probe 600, a cover 700, an adjusting screw 800 and a fixing screw 900.

The upper stiffener 100 is disposed below the printed circuit board 200, and protects the printed circuit board 200 from an external shock or the like. The upper stiffener 100 includes a first screw hole 110 into which a later described fixing screw 900 is inserted.

The printed circuit board 200 is disposed on the upper gusset plat 100.

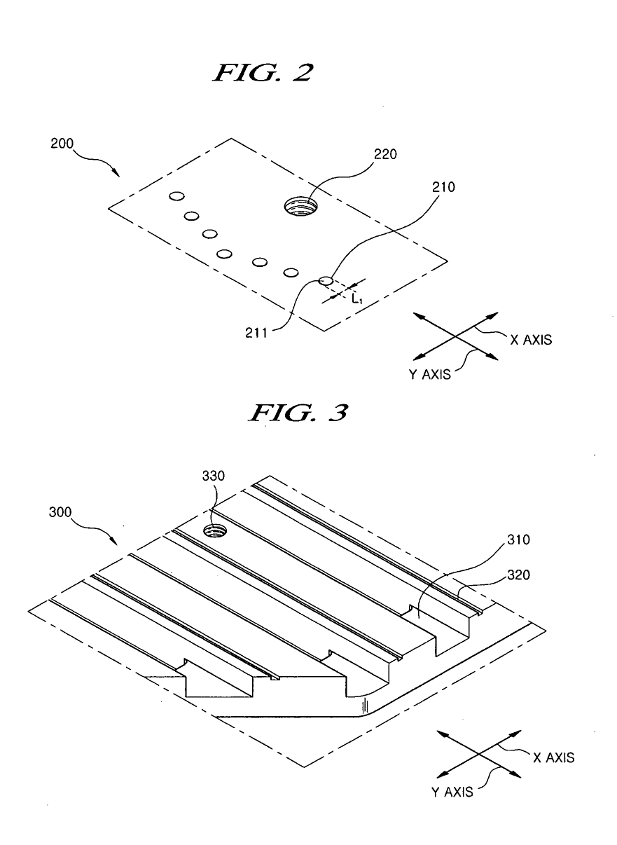

FIG. 2 is an enlarged view illustrating A portion of FIG. 1.

As illustrated in FIG. 2, the printed circuit board 200 has a disk shape and has a probe circuit pattern (not shown) for a test process formed thereon. The printed circuit board 200 includes a substrate through hole 210 and a second screw hole 220 through which a fixing screw 900 passes.

The substrate through hole 210 extends by passing through the printed circuit board 200. A conductive material 211 is formed on an inner surface of the through hole 210, and the conductive material 211 is connected with the probe circuit pattern (not shown). The substrate through holes 210 are sequentially spaced apart from each other in X axis and Y axis directions. The width of the substrate through hole 210 in X axis and Y axis directions has a first length L₁.

In the printed circuit board 200, in order to test a highly integrated wafer, a pitch can be changed to the substrate through hole 210 by the probe circuit pattern (not shown) in the printed circuit board 200. The printed circuit board 200 can be connected to a tester used for testing.

A lower stiffener 300 is disposed on the printed circuit board 200.

FIG. 3 is an enlarged view illustrating B portion of FIG. 1.

As illustrated in FIG. 3, the lower stiffener 300 protects the later described probe substrate 500 from the external shocks, and includes a receiving groove 310, a grooved rail 320, and a third screw hole 330 through which the fixing screw 900 passes.

The receiving groove 310 is extended in the Y axis direction. A center portion of the receiving groove 310 extends by passing through the lower stiffener 300, and an end portion of the receiving groove 310 is depressed from an upper surface of the lower stiffener 300. The receiving groove 310 receives the later described guide block 400.

The grooved rail 320 is depressed from the upper surface of the lower stiffener 300 and extended in the Y axis direction. The grooved rail 320 receives a later described protruded rail 514 of the probe substrate 500, and restrains the probe substrate 500 from moving in the X axis direction.

The guide block 400 is disposed on the lower stiffener 300, and corresponds to the receiving groove 310 of the lower stiffener 300.

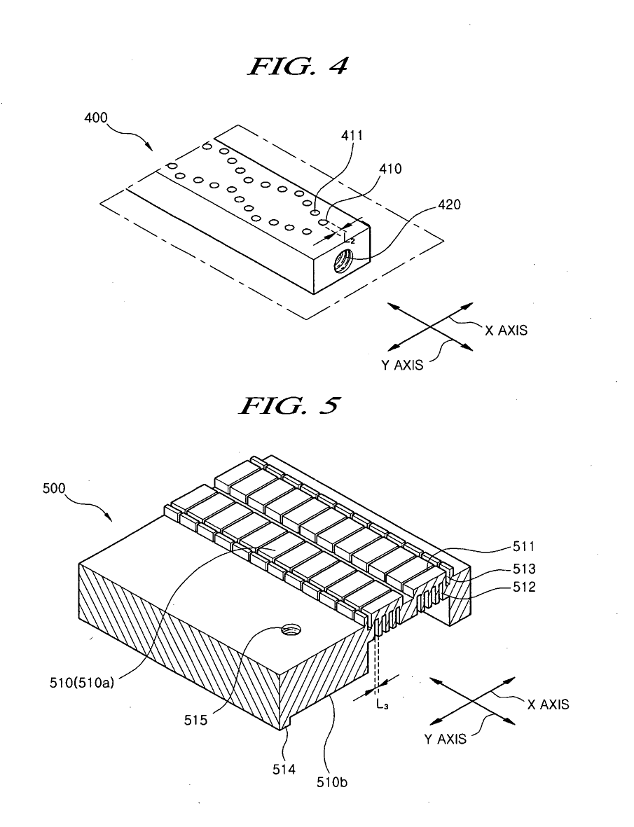

FIG. 4 is an enlarged view illustrating C portion of FIG. 1.

As illustrated in FIG. 4, the guide block 400 has a rod shape and is extended in the Y axis direction, and the plural guide blocks are spaced apart from each other in the X axis direction. An end portion of the guide block 400 is settled on the end portion of the receiving groove 310, and the guide block 400 is received in the receiving groove 310 formed on the lower stiffener 300. Preferably, the length of the guide block in the Y axis direction is formed shorter than the length of the receiving groove 310 in the Y axis direction so that the guide block 400 slides along the receiving groove 310 in the Y axis direction.

The guide block 400 includes a block through hole 410 and an adjusting screw groove 420 into which a later described adjusting screw 800 is inserted.

The block through hole 410 is disposed on a position corresponding to the substrate through hole 210 of the printed circuit board 200 by passing through the guide block 400. On an inner surface of the block through hole 410, a conductive material 411 is formed. The block through holes 410 are sequentially spaced apart from each other in the X axis and Y axis directions. The width of the block through hole 410 in the X axis and Y axis directions is a second length L₂.

The probe substrate 500 is disposed on the guide block 400.

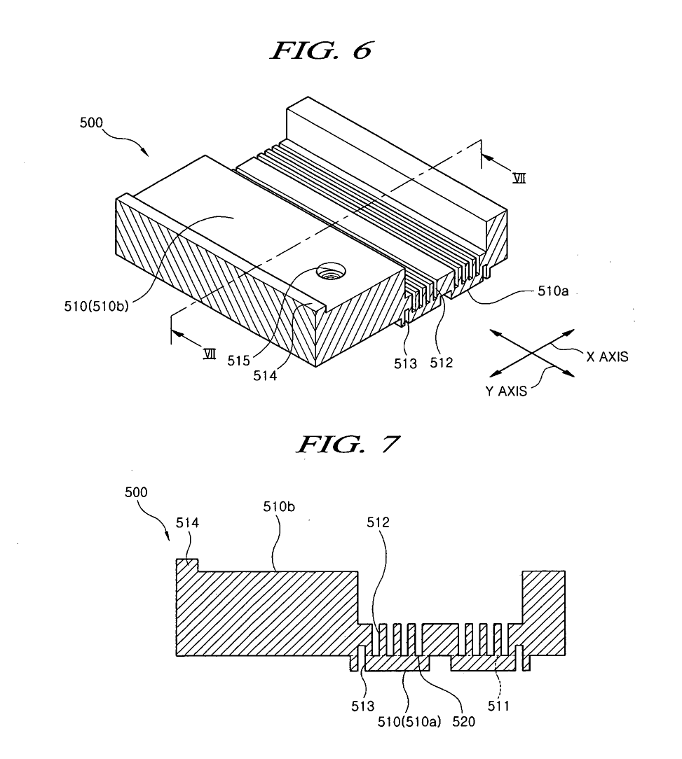

FIG. 5 is an enlarged view illustrating D portion of FIG. 1, FIG. 6 depicts a rear view of FIG. 5 and FIG. 7 shows a cross sectional view taken along line VII-VII in FIG. 6.

As illustrated in FIGS. 5 thru 7, the probe substrate 500 includes a probe substrate body 510 and a probe through hole 520.

The probe substrate body 510 is made of a ceramic substrate, and includes a fixing slit 511, a first groove 512, a second groove 513, a protruded rail 514 and a fourth screw hole 515.

The fixing slit 511 is depressed from a first surface 510a of the probe substrate body 510, and is extended in the X axis direction. Onto the fixing slit 511, a later described probe body 610 of the probe 600 is mounted. A width of the fixing slit 511 in the Y axis direction is substantially equal to a thickness of the probe 600 which will be described later, thereby restraining the probe 600 mounted on the fixing slit 511 from moving in the Y axis direction.

The first groove 512 is depressed from the second surface 510b of the probe substrate body 510, and is extended in the Y axis direction. A width of the first groove 512 in the X axis direction is a third length L₃.

The fixing slit 511 and the first groove 512 is formed by a dicing process which uses a saw having high hardness like a diamond, and a probe through hole 520 is formed in a portion where the fixing slit 511 and the first groove 512 are cross-intersecting. In other words, the probe through hole 520 is formed by communicating the fixing slit 511 with the first groove 512.

The probe through hole 520 extends by passing through the probe substrate body 510, and a later described probe lead part 640 of a probe 600 passes through the probe through hole 520. Since the probe through hole 520 is formed by the fixing slit 511 and the first groove 512, a width of the probe through hole 520 in the X axis direction is the third length L₃ which is the width of the first groove 512 in the X axis direction.

The second groove 513 is depressed from the first surface 510a of the probe substrate body 510, and is extended in the Y axis direction. The second groove 513 is depressed from the first side 510a by a depth deeper than the fixing slit 511, and a later described protruded part 620 is inserted therein. The width of the second groove 513 in the X axis direction is substantially equal to the width of the protruded part 620 of the probe 600 in the X axis direction, thereby restraining the probe 600 mounted on the fixing slit 511 from moving in the X axis direction. The second groove 513 can be formed by the dicing process.

The protruded rail 514 protrudes from the first surface 510a of the probe substrate body 510, and is extended in the Y axis direction. The protruded rail 514 is inserted into the grooved rail 320 of the lower stiffener 300, and restrains the probe substrate 500 from moving in the X axis direction.

The fourth screw hole 515 extends by passing through the probe substrate body 510, and in order to allow a head of the later described fixing screw 900 to be inserted, a portion formed on the second surface 510b is larger than a portion formed on the first surface 510a.

In another embodiment, at least one of the fixing slit 511, the first groove 512, the probe through hole 520 and the second groove 513 can be formed through a photolithography process.

On the probe substrate 500, a plurality of probes 600 are mounted.

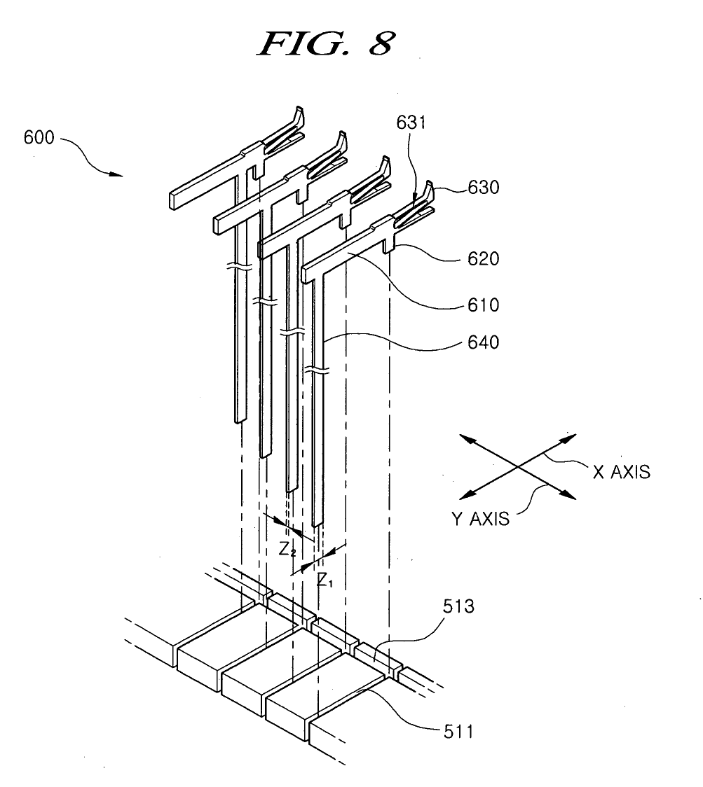

FIG. 8 is an enlarged perspective view illustrating a portion among a plurality of probes illustrated in FIG. 1.

As illustrated in FIG. 8, the probe 600 has a plate shape and includes the probe body 610, the protruded part 620, a tip part 630 and the probe lead part 640.

The probe body 610 has a rod shape and is inserted into the fixing slit 511 of the probe substrate 500. A width of the probe body 610 in the Y axis direction, which is a thickness thereof, is substantially equal to a width of the fixing slit 511 in the Y axis direction. In the probe body 610, the movement in the Y axis direction is restrained by the fixing slit 511. In other words, the probes 600 are arranged in the Y axis direction.

The protruded part 620 protrudes from the probe body 610 toward the probe substrate 500, and is inserted into the second grove 513 of probe substrate 500. A width of the protruded part 620 in the X axis direction is substantially equal to a width of the second groove 513 in the X axis direction. In the protruded part 620, the movement in the X axis direction is restrained by the second groove 513. In other words, the probes 600 are arranged in the X axis direction.

The tip part 630 has an elastic portion 631, and serves to make contact with the contact pads formed on the wafer during the test process. The tip part 630 elastically deals with the contact pads formed on the wafer by the elastic portion 631.

The probe lead part 640 protrudes from the probe body 610 toward the printed circuit board 200, and passes through the probe through hole 520 of the probe substrate 500, the first groove 512, the block through hole 410 of the guide block 400 and the receiving groove 310 of the lower stiffener 300 to be inserted into the substrate through hole 210 of the printed circuit board 200. An end portion of the probe lead part 640 is disposed in the substrate through hole 210 of the printed circuit board 200. The probe lead part 640 has a first width Z₁ in the X axis direction, and a second width Z₂ in the Y axis direction.

Among the plurality of the probes 600, each probe lead part 640 of the adjacent probes 600 is connected to each probe body 610 at different locations. More specifically, each probe lead part 640 of the respective probes 600 arranged in the Y axis direction is deviated from each other in the X axis direction. Therefore, since the distance between the adjacent probe lead parts 640 becomes more distant, a mutual interference caused by an electrical wave which can be generated at each probe lead part 640 by an electrical signal, which is transferred from the tester to each probe lead part 640 during the test process. In addition, since the distance between the adjacent probe lead parts 640 becomes more distant, the probe 600 can be connected with the printed circuit board 100 without using the space transformer.

The cover 700 is disposed on a contour formed by the probe substrate 500, the guide block 400 and the lower stiffener 300 through which the probe lead part 640 passes.

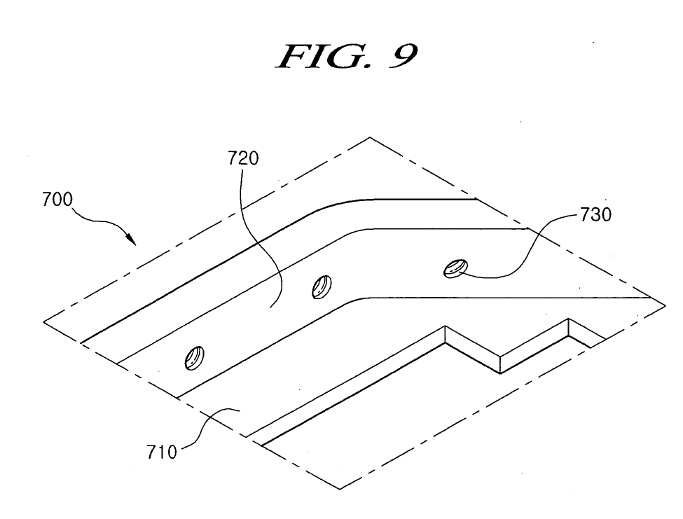

FIG. 9 is a rear view of E portion of FIG. 1.

As illustrated in FIG. 9, the cover 700 includes a hollow part 710, a protruded wall 720, and an adjusting screw hole 730.

The hollow part 710 has a closed loop shape whose center portion is hollow so that the probe body 610 of the probe 600 is exposed. The hollow part 710 is disposed in correspondence with a peripheral portion of the probe substrate 500. The hollow part 710 upwardly supports the probe substrate 500, the guide block 400 and the lower stiffener 300 by supporting the probe substrate 500 upwardly.

The protruded wall 720 is bent toward the printed circuit board 200 along a peripheral portion of the hollow part 710, and surrounds the contour formed by the probe substrate 500, the guide block 400 and the lower stiffener 300. The protruded wall 720 is coupled to the printed circuit board 200, and fixes the contour formed by the probe substrate 500, the guide block 400 and the lower stiffener 300, thereby supporting the probe substrate 500, the guide block 400 and the lower stiffener 300 in a horizontal direction.

The adjusting screw hole 730 is formed in a position corresponding to the guide block 400 by passing through the projected wall 720, and a female thread corresponding to a male thread of the adjusting screw 800 is formed inside thereof.

The adjusting screw 800 is coupled to the adjusting screw hole 730.

Again, as illustrated in FIG. 1, the adjusting screw 800 passes through the adjusting hole 730 of the cover 700 to be fixedly inserted into the adjusting screw groove 420 of the guide block 400. By turning the adjusting screw 800 in a clockwise or a counterclockwise direction, the adjusting screw 800 is pushed or pulled in the Y axis direction in the adjusting screw hole 730, and by a movement of the adjusting screw 800, the guide block 400 is pushed or pulled in the Y axis direction.

In a direction intersecting with the adjusting screw 800, the fixing screw 900 is coupled to the probe substrate 500.

The fixing screw 900 is inserted into the first screw hole 110 of the upper stiffener 100 by passing through the fourth screw hole 515 of the probe substrate 500, the third screw hole 330 of the lower stiffener 300 and the second screw hole 220 of the printed circuit board 200. The upper stiffener 100, the printed circuit board 200, the lower stiffener 300, the guide block 400 and the probe substrate 500 are mutually supported by the fixing screw 900.

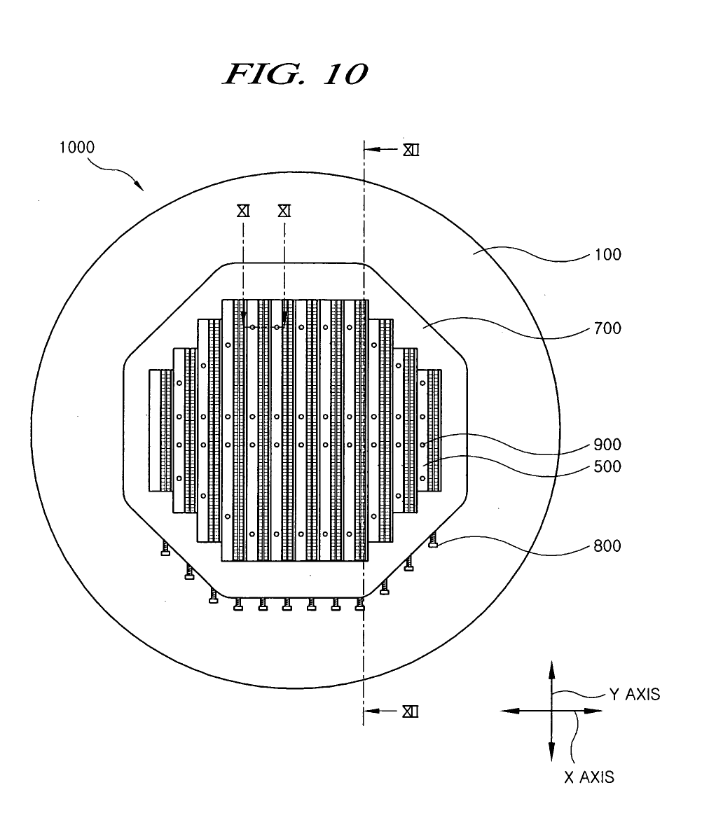

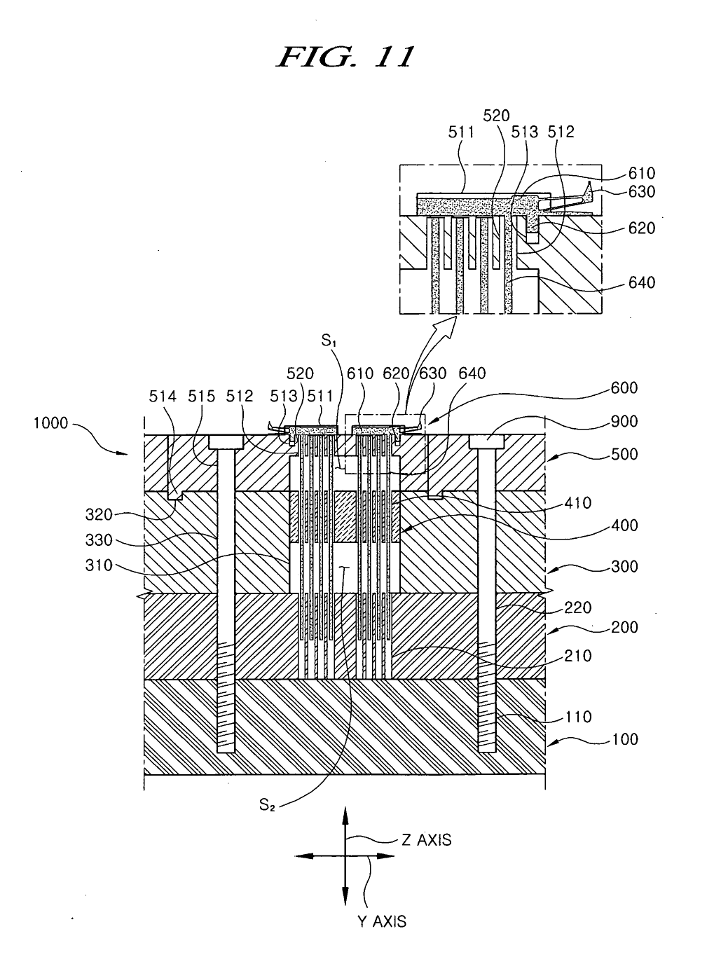

Hereinafter, in reference to FIGS. 10 and 11, a specific coupling structure of the probe card in accordance with the first embodiment of the present invention will be described.

FIG. 10 is a plan view of the probe card in accordance with the first embodiment of the present invention and FIG. 11 is a cross sectional view taken along line XI-XI of FIG. 10.

As illustrated in FIGS. 10 and 11, the printed circuit board 200, the lower stiffener 300 and the probe substrate 500 are sequentially disposed on the upper stiffener 100, and the guide block 400 is inserted into the receiving groove 310.

The protruded rail 514 of the probe substrate 500 is inserted into the grooved rail 320 of the lower stiffener 300.

A first space S1 is formed between the probe substrate 500 and the guide block 400, and a second place S2 is formed between the guide block 400 and the printed circuit board 200. The first space S1 corresponds to the first groove 512 of the probe substrate 500, and the second space S2 corresponds to the receiving groove 310 of the lower stiffener 300. In other words, the probe 600, the first groove 512, the guide block 400, the second space S2 and the printed circuit board 200 are disposed on a Z axis substantially perpendicular to the X axis.

The probe body 610 of the probe 600 is inserted into the fixing slit 511 of the probe substrate 500, and the tip part 630 is extended to an exterior of the fixing slit 511. The protruded part 620 of the probe 600 is inserted inside of the second groove 513, and the probe lead part 640 is inserted into the substrate through hole 210 of the printed circuit board 200 by passing through the probe through hole 520 of the probe substrate 500, the first space S1, the block through hole 410 of the guide block 400 and the second space S2.

The first width Z1 of the probe lead part 640 in the X axis direction is narrower than the third length L3 which is the width of the probe through hole 520 in the X axis direction, the second length L2 which is the width of the block through hole 410 in the X axis direction and the first length L1 which is the width of the through hole 210 in the X axis direction. More specifically, the probe lead part 640 is freely extended with enough space in the X axis direction within the probe through hole 520, the block through hole 410 and the substrate through hole 210. In other words, the probe through hole 520, the block through hole 410 and the substrate through hole 210 are formed so that the probe lead part 640 can be freely extended.

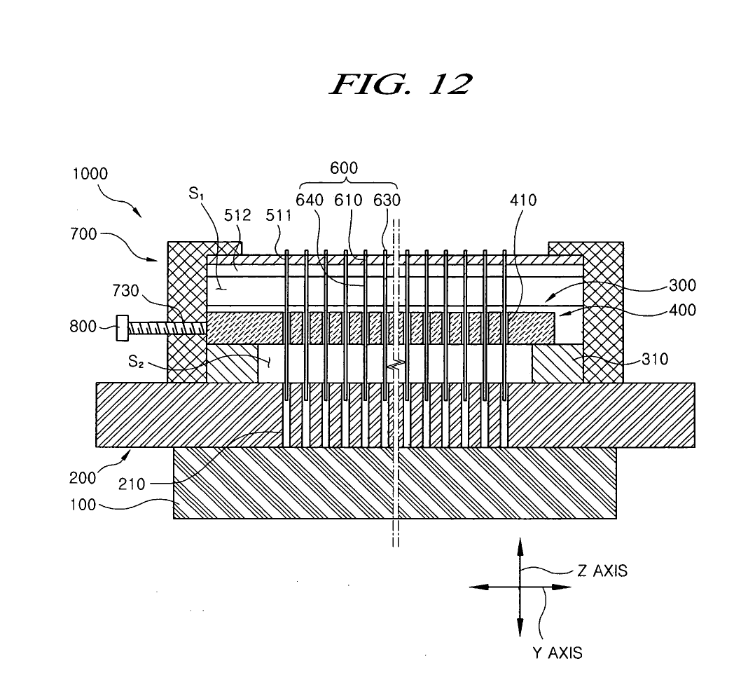

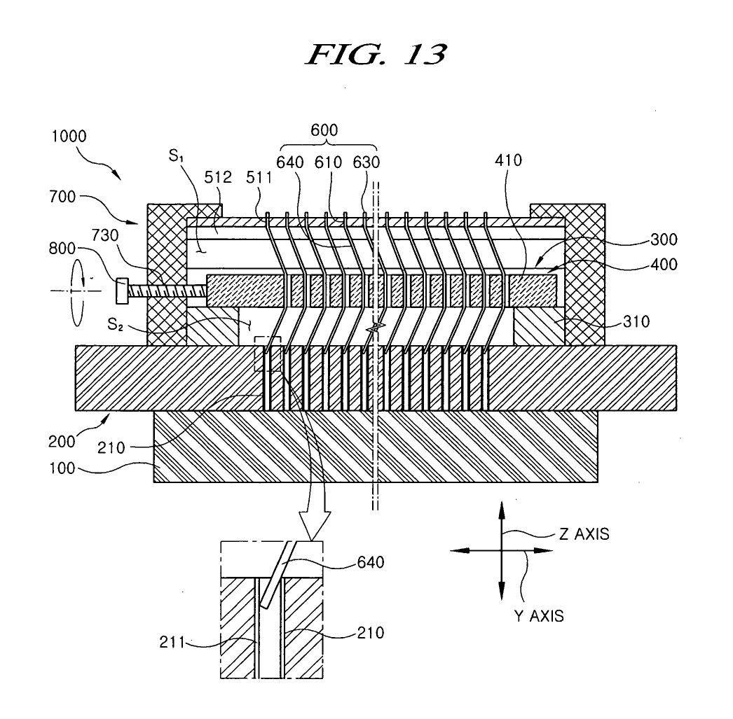

Hereinafter, in reference to FIGS. 12 and 13, a connection between the probe and the printed circuit board in the probe card by the sliding of the guide block in accordance with the first embodiment of the present invention will be described.

FIG. 12 is a cross sectional view taken along line XII-XII of FIG. 10 and FIG. 13 is a cross sectional view when the guide block is moved in FIG. 12.

As illustrated in FIG. 12, since the width of the probe body 610 in the Y axis direction, that is, the thickness of the probe body 610 of the probe 600 is substantially equal to the width of the fixing slit 511 of the probe substrate 500 in the Y axis direction, the probe body 610 is arranged in the Y axis direction on the fixing slit 511.

The probe lead part 640 of the probe 600 can move freely within the first groove 512, the first space S1 and the second space S2 of the probe substrate 500 in the Y axis direction. In addition, the second width Z2 of the probe lead part 640 in the Y axis direction is narrower than the second length L2 which is the width of the block through hole 410 in the Y axis direction and the first length L2 which is the width of the substrate through hole 210 in the Y axis direction. In other words, since the probe lead part 640 is loosely mounted on the probe substrate 500, the guide block 400 and the printed circuit board 200, the probe 600 can be freely detached from the probe substrate 500 in the Z axis direction without the substantial interference of the probe substrate 500, the guide block 400 and the printed circuit board 200.

As illustrated in FIG. 13, if the adjusting screw 800 is turned in the clockwise or counterclockwise direction to push the adjusting screw 800 towards the Y axis direction, the guide block 400 coupled to the adjusting screw 800 is pushed in the Y axis direction. By such movement of the guide block 400 in the Y axis direction, a part of the probe lead part 640 disposed within the block through hole 410 of the guide block 400 becomes bent in the Y axis direction. Due to the bending of the part of the probe lead part 640, the whole probe lead part 640 bends in the Y axis direction, so that an end portion of the probe lead part 640 which is disposed in the substrate through hole 210 makes contact with an inner surface of the substrate through hole 210. Since the conductive material 211 is formed on the inner surface of the substrate through hole 210 and is connected with the probe circuit pattern formed on the printed circuit board 200, the probe 600 is electrically connected to the printed circuit substrate 200 by a contact between the probe lead part 640 and the substrate through hole 210.

Also, due to the bending of the probe lead part 640 in the Y axis direction, the probe lead part 640 restrains the movement of the probe 600 in the Z axis direction. More specifically, the probe 600 is arranged in the Z axis direction.

In other words, the probe 600 is connected to the printed circuit board 200 by movement of the guide block 400 in the Y axis direction by using the adjusting screw 800, and the probe 600 is restrained from moving in the Z axis direction.

Additionally, if the guide block 400 is pulled back to an initial position by using the adjusting screw 800, the probe 600 can be freely detached from the probe substrate 500 in the Z axis direction.

As described above, in the probe card in accordance with the first embodiment of the present invention, since the electrical connection between the probe circuit pattern formed on the printed circuit board 200 and the probe 600 is performed without an additional bonding process between the probe circuit pattern and the probe 600, the manufacturing time and the manufacturing costs of the probe card are reduced.

Additionally, since the probe 600 makes contact with the probe circuit pattern formed on the printed circuit board 200 by the movement of the guide block 400 in the Y axis direction, it is unnecessary to equally adjust the structural shapes of the probe lead part 640 and the substrate through hole 210 of the printed circuit board 200 which are related to the contact, or it is unnecessary to require an additional member related to the contact. Thus, the manufacturing time and the manufacturing costs of the probe card are reduced.

Moreover, when the defect occurs on some of the probes 600 during the plural test processes, the guide block 400 is pulled to the initial position in the Y axis direction to free all of the probes 600 in the Z axis direction. Then, the defected probe 600 is separated from the probe card 1000 and the new probe is inserted therein. Then, by pushing the guide block 400 in the Y axis direction, the repair work of the probe card 1000, in which the probes 600 are arranged in the X axis, Y axis and Z axis directions, is completed.

In addition, since the arrangement of the probe 600 in the X axis direction by the second groove 513 of the probe substrate 500 and the arrangement of the probe 600 the Y axis direction by the fixing slit 511 are achieved, the movements of the probe 600 in the X and Y axis directions are restrained during the test process so that the probe 600 can make contact with a desired position.

Also, since the arrangement of the probe 600 in the Z axis direction is achieved by the movement of the guide block 400 in the Y axis direction, the movements of the probe 600 in the X axis, Y axis and Z axis directions are restrained during the test process, so that the probe 600 can make contact with a desired position. In other words, the probe card 1000 having improved contact reliability is provided.

In addition, since the probe through hole 520 is formed by communicating the fixing slit 511 extended in the X axis direction with the first groove 512 extended in the Y axis direction, it is unnecessary to form the probe through hole 520, which passes through-the probe lead part 640 for electrically connecting the printed circuit board 200, through an additional process. Thus, the manufacturing time and the manufacturing costs of the probe card are reduced.

Additionally, if the size of the probe 600 needs to be changed, the size of the probe substrate 500 and the probe 600 can be changed or the number of the probe substrate 500 can be increased to be applicable for the conventional probe card 1000. Thus, the probe card can be widely used.

Accordingly, the probe card in accordance with the embodiment of the present invention is capable of reducing the manufacturing time, the manufacturing costs and the maintenance costs thereof by simplifying the manufacturing process and the repair work thereof.

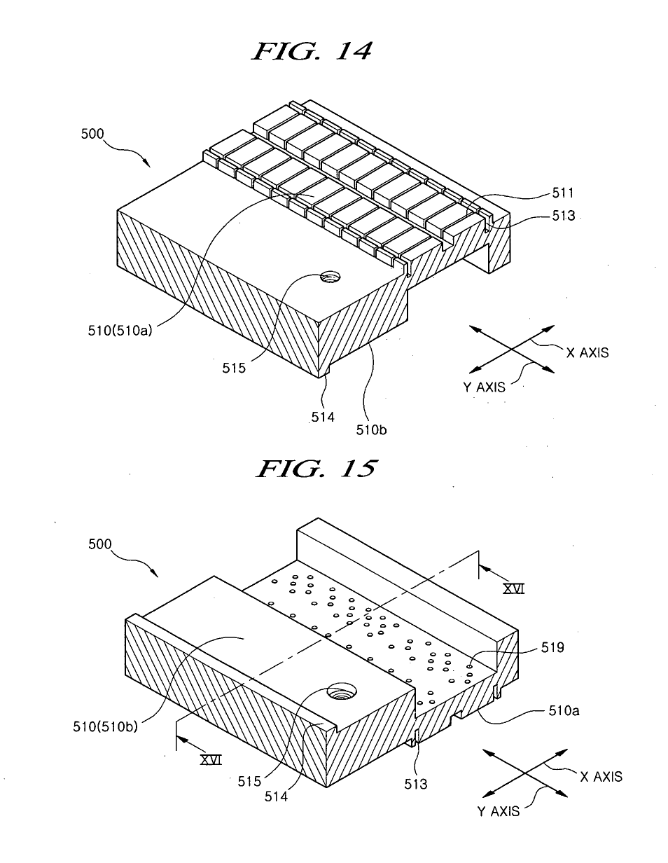

Hereinafter, in reference to FIGS. 14 to 16, a probe card in accordance with a second embodiment of the present invention will be described.

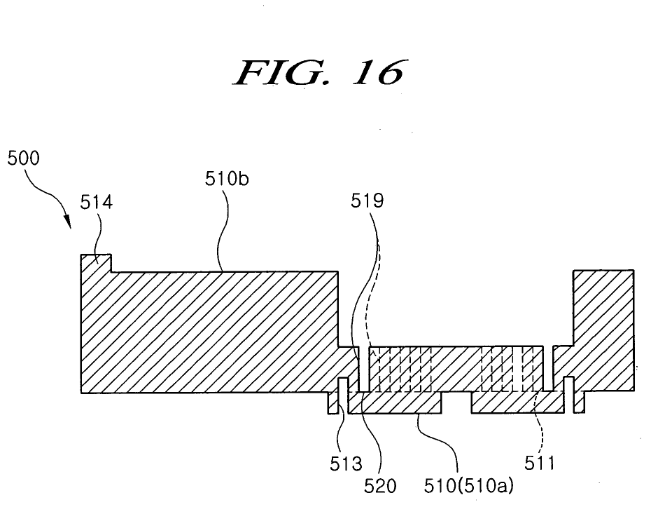

FIG. 14 is a partially enlarged perspective view of the probe substrate included in the probe card in accordance with the second embodiment of the present invention, FIG. 15 is a rear view of FIG. 14 and FIG. 16 is a cross sectional view taken along line XVI-XVI of FIG. 15.

Hereinafter, like reference numerals denote like and corresponding components to those in the first embodiment and explanation about them is omitted for convenience sake.

As illustrated in FIGS. 14 to 16, a probe substrate 500 includes a probe substrate body 510 and a probe through hole 520.

The probe substrate body 510 is made of a ceramic substrate, and includes a fixing slit 511, a guide hole 519, a second groove 513, a protruded rail 514 and a fourth screw hole 515.

The fixing slit 511 is depressed from a first surface 510a of the probe substrate body 510, and is extended in an X axis direction. On the fixing slit 511, a probe body 610 of a probe 600 is mounted. A width of the fixing slit 511 in a Y axis direction is substantially equal to a thickness of the probe 600. Thus, the probe 600 mounted on the fixing slit 511 is restrained from moving in the Y axis direction.

The guide hole 519 is depressed from a second surface 510b of the probe substrate body 510, and a plurality of guide holes 519 are formed in a position corresponding to a position where a plurality of probes lead parts 640 are inserted.

The fixing slit 511 is formed by a dicing process which uses a saw having high hardness like a diamond, and the guide hole 519 is formed by a drilling process which uses a drill. The probe through hole 520 is formed in a portion where the fixing slit 511 and the guide hole 519 are cross-intersecting. In other words, the probe through hole 520 is formed by communicating the fixing slit 511 with the guide hole 519.

Thus, the probe card in accordance with the embodiment of the present invention is capable of reducing the manufacturing time, the manufacturing costs and the maintenance costs thereof by simplifying the manufacturing process and the repair work thereof.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure.

The scope of the present disclosure is defined by the following claims rather than by the detailed description of the embodiment. It shall be understood that all modifications and embodiments conceived from the meaning and scope of the claims and their equivalents are included in the scope of the present disclosure.

What is claimed is:

1. A probe card comprising:
a printed circuit board including a substrate through hole;
at least one probe substrate disposed on the printed circuit board;
at least one probe including a probe body supported by the probe substrate and a probe lead part extending from the probe body to an inside of the substrate through hole in the printed circuit board; and
a guide block disposed between the printed circuit board and the probe substrate, and including a block through hole through which the probe lead part passes,
wherein the probe is fixed to the probe substrate by moving the guide block in a Y axis direction so that the probe lead part is bent in the Y axis direction.

2. The probe card of claim 1, wherein the substrate through hole of the printed circuit board and the block through hole of the guide block are formed so that the probe lead part is freely extended.

3. The probe card of claim 1, wherein a conductive material is formed on an inner surface of the substrate through hole, and an end portion of the probe lead part is supported by the conductive material while making contact with the conductive material when the probe lead part is bent in the Y axis direction.

4. The probe card of claim 1, wherein a conductive material is formed on an inner surface of the block through hole, and a center portion of the probe lead part is supported by the conductive material while making contact with the conductive material when the probe lead part is bent in the Y axis direction.

5. The probe card of claim 1, further comprising a first space formed between the probe substrate and the guide block and a second space formed between the guide block and the printed circuit board so that the probe lead part is bent.

6. The probe card of claim 1, further comprising a lower stiffener disposed between the guide block and the printed circuit board.

7. The probe card of claim 6, wherein the lower stiffener includes at least one receiving groove extending in the Y axis direction, and the guide block is received in the receiving groove.

8. The probe card of claim 7, wherein a protruded rail extending in the Y axis direction is formed on one side surface of the lower stiffener and the probe substrate which are facing each other, and a grooved rail structurally coupled to the protruded rail is formed on the other side surface of the lower stiffener and the probe substrate.

9. The probe card of claim 1, further comprising a cover which surrounds a contour of the probe substrate and a contour of the guide block.

10. The probe card of claim 9, wherein the cover includes a hollow part formed to expose the probe body and a protruded wall formed along a peripheral portion of the hollow part.

11. The probe card of claim 1, further comprising an adjusting screw which passes through the protruded wall to be coupled to a side surface of the guide block, wherein the guide block is pushed or pulled in the Y axis direction by turning the adjusting screw.

12. The probe card of claim 1, wherein the probe substrate includes a probe substrate body and at least one probe through hole which is formed by passing through the probe substrate body.

13. The probe card of claim 12, wherein the probe substrate body includes a ceramic substrate.

14. The probe card of claim 13, wherein the probe through hole is formed by a photolithography process.

15. The probe card of claim 12, wherein the probe substrate body includes at least one fixing slit which extends in an X axis direction at one side surface of the probe substrate body where the probe body is exposed, and has a width substantially equal to a thickness of the probe; and
at least some of the probe bodies are received in the fixing slit so that the probes are arranged in the Y axis direction.

16. The probe card of claim 15, wherein the probe substrate body further includes at least one first groove which extends in the Y axis direction at the other side surface facing the one side surface; and
the probe through hole is formed in an intersecting portion of the fixing slit and the first groove.

17. The probe card of claim 16, wherein the fixing slit and the first groove are formed by a dicing process.

18. The probe card of claim 15, wherein the probe substrate body further includes at least one guide hole which extends from the other side surface facing the one side surface to the fixing slit; and
the probe through hole is formed by communicating the fixing slit with the guide hole.

19. The probe card of claim 18, wherein the fixing slit is formed by a dicing process and the guide hole is formed by a drilling process.

20. The probe card of claim 15, wherein the probe substrate body further includes at least one second groove which extends in the Y axis direction at the one side surface of the probe substrate body where the probe body is exposed, and the probe body has a width substantially equal to a width of the second groove; and
a protruded part is received in the second groove so that the probes are arranged in the X axis direction.

21. The probe card of claim 1, wherein each probe lead part of the adjacent probes is connected with each probe body at different positions.

22. The probe card of claim 1, further comprising an upper stiffener which is disposed on an upper part of the printed circuit board.

23. The probe card of claim 22, further comprising a probe substrate fixing screw which is inserted into the probe substrate to be coupled with the upper stiffener.
